(19) United States
(12) Patent Application Publication
(10) Pub. No.: US 2024/0155776 A1
(43) Pub. Date: May 9, 2024

(54) PRINTED WIRING BOARD

(71) Applicant: IBIDEN CO., LTD., Ogaki (JP)

(72) Inventors: JUN SAKAI, Ogaki (JP); KYOHEI YOSHIKAWA, Ogaki (JP)

(73) Assignee: IBIDEN CO., LTD., Ogaki (JP)

(21) Appl. No.: 18/502,209

(22) Filed: Nov. 6, 2023

(30) Foreign Application Priority Data
Nov. 8, 2022 (JP) 2022-179101

(51) Int. Cl. H05K 3/42; H05K 1/03; H05K 1/11

(52) U.S. Cl. CPC H05K 3/429; H05K 1/0306; H05K 1/114; H05K 2201/096

(57) ABSTRACT

A printed wiring board includes a conductor layer including a pad, a first resin insulating layer laminated on the conductor layer, a first conductor layer formed on the first resin insulating layer and including a first seed layer and a first electrolytic plating layer, a second resin insulating layer laminated on the first insulating layer such that the second resin insulating layer is covering the first conductor layer, and a second conductor layer formed on the second resin insulating layer and including a second seed layer and a second electrolytic plating layer. The first conductor layer is formed such that the first seed layer is an electroless plating layer and the first electrolytic plating layer formed on the first seed layer, and the second conductor layer is formed such that a second seed layer is a sputtering layer and the second electrolytic plating layer formed on the second seed layer.

### CROSS-REFERENCE TO RELATED APPLICATIONS

The present application is based upon and claims the benefit of priority to Japanese Patent Application No. 2022-179101, filed Nov. 8, 2022, the entire contents of which are incorporated herein by reference.

### BACKGROUND OF THE INVENTION

### Field of the Invention

The present invention relates to a printed wiring board.

### DESCRIPTION OF BACKGROUND ART

Japanese Patent Application Laid-Open Publication No. 2000-124602 describes a method for manufacturing a printed wiring board. The entire contents of this publication are incorporated herein by reference.

### SUMMARY OF THE INVENTION

According to one aspect of the present invention, a printed wiring board includes a conductor layer including a pad, a first resin insulating layer laminated on the conductor layer, a first conductor layer formed on the first resin insulating layer and including a first seed layer and a first electrolytic plating layer formed on the first seed layer, a second resin insulating layer laminated on the first resin insulating layer such that the second resin insulating layer is covering the first conductor layer, and a second conductor layer formed on the second resin insulating layer and including a second seed layer and a second electrolytic plating layer formed on the second seed layer. The first conductor layer is formed such that the first seed layer is an electroless plating layer and the first electrolytic plating layer formed on the first seed layer, and the second conductor layer is formed such that a second seed layer is a sputtering layer and the second electrolytic plating layer formed on the second seed layer.

According to another aspect of the present invention, a printed wiring board includes a first conductor layer, a first resin insulating layer laminated on the first conductor layer, a second conductor layer formed on the first resin insulating layer, a first via conductor formed in a first opening formed in the first resin insulating layer such that the first via conductor is connecting the first conductor layer and the second conductor layer, a second resin insulating layer laminated on the first resin insulating layer such that the second resin insulating layer is covering the second conductor layer formed on the first resin insulating layer, a third conductor layer formed on the second resin insulating layer, and a second via conductor formed in a second opening formed in the second resin insulating layer such that the second via conductor is connecting the second conductor layer and the third conductor layer. The first via conductor includes a first seed layer including a sputtering layer and a first electrolytic plating layer formed on the first seed layer such that the first via conductor does not have voids in a connecting portion between the first conductor layer and the first via conductor, and the second via conductor includes a second seed layer including an electroless plating layer and a second electrolytic plating layer formed on the second seed layer such that the second via conductor has voids in a connecting portion between the second via conductor and the second conductor layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2A is an enlarged cross-sectional view schematically illustrating a part of a printed wiring board according to an embodiment of the present invention;

FIG. 2B is an enlarged cross-sectional view schematically illustrating a part of a printed wiring board according to an embodiment of the present invention;

FIG. 3 is an enlarged cross-sectional view schematically illustrating a part of a printed wiring board according to an embodiment of the present invention;

FIG. 4 is an enlarged cross-sectional view schematically illustrating a part of a printed wiring board according to an embodiment of the present invention; and

FIGS. 5A to 5M are cross-sectional views schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Embodiment

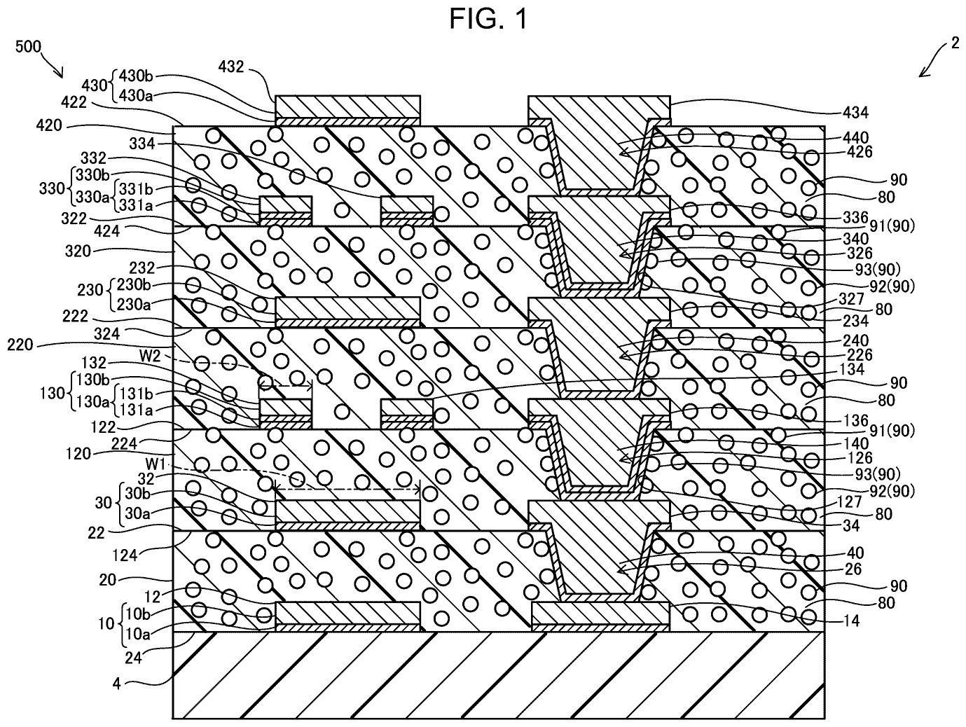

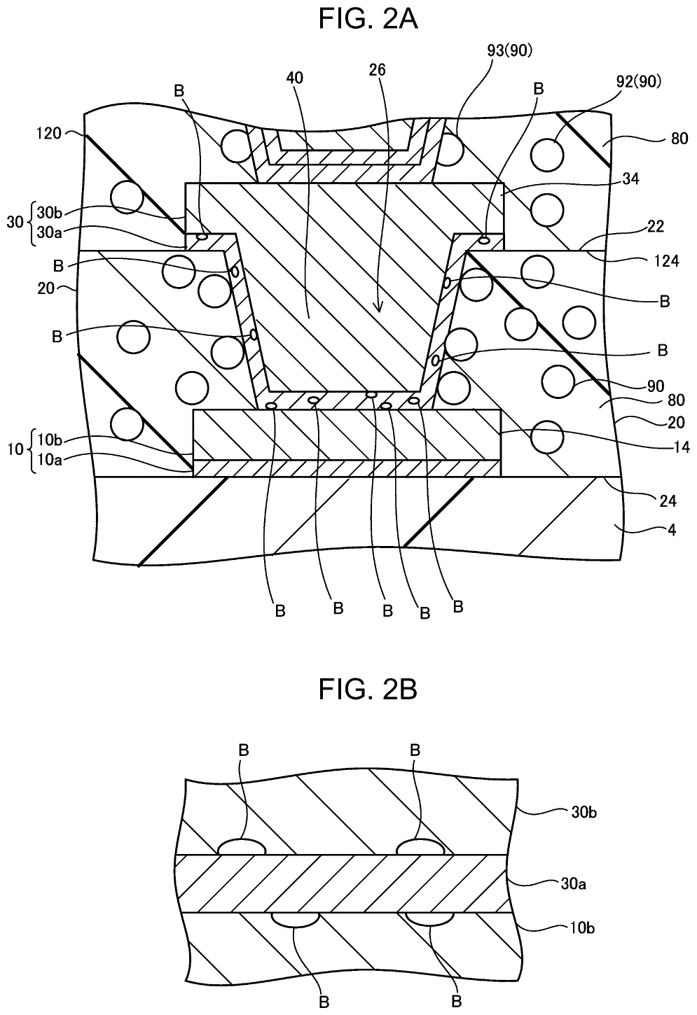

FIG. 1 is a cross-sectional view illustrating a printed wiring board 2 according to an embodiment of the present invention. FIGS. 2A-4 are each an enlarged cross-sectional view illustrating a part of the printed wiring board 2 of the embodiment. As illustrated in FIG. 1, the printed wiring board 2 includes an insulating layer 4, a conductor layer 10, and a build-up layer 500. The conductor layer 10 is formed on the insulating layer 4. The build-up layer 500 is formed on the insulating layer 4 and the conductor layer 10.

The insulating layer 4 is formed using a resin. The insulating layer 4 may contain inorganic particles such as silica particles. The insulating layer 4 may contain a reinforcing material such as a glass cloth. The insulating layer 4 may be a core substrate.

The conductor layer 10 is formed on the insulating layer 4. The conductor layer 10 includes a solid pattern 12 and a pad 14. Although not illustrated in the drawings, the conductor layer 10 also includes conductor circuits other than the solid pattern 12 and the pad 14. The conductor layer 10 is mainly formed of copper. The conductor layer 10 is formed of a seed layer (10a) on the insulating layer 4 and an electrolytic plating layer (10b) on the seed layer (10a). The seed layer (10a) has a thickness of less than 0.5 The seed layer (10a) is an electroless plating layer formed by electroless plating. In a modified example, the seed layer (10a) may be a sputtering layer formed by sputtering. When the seed layer (10a) is a sputtering layer, the seed layer (10a) may be formed of a first layer on the insulating layer 4 and a second layer on the first layer. The first layer is formed of an alloy (copper alloy) containing copper and a specific base metal. The specific base metal is a base metal other than copper. The specific base metal is, for example, aluminum. The second layer is formed of copper.

The build-up layer 500 is formed on the insulating layer 4 and the conductor layer 10. The build-up layer 500 includes multiple resin insulating layers and multiple conductor layers. The resin insulating layers and the conductor layers are alternately laminated. In the build-up layer 500 of FIG. 1, there are five resin insulating layers and five conductor layers.

The resin insulating layers in the build-up layer 500 include a first resin insulating layer 20, a second resin insulating layer 120, a third resin insulating layer 220, a fourth resin insulating layer 320, and a fifth resin insulating layer 420. The first resin insulating layer 20, the second resin insulating layer 120, the third resin insulating layer 220, the fourth resin insulating layer 320, and the fifth resin insulating layer 420 respectively have a first opening 26, a second opening 126, a third opening 226, a fourth opening 326, and a fifth opening 426.

The conductor layers in the build-up layer 500 include a first conductor layer 30, a second conductor layer 130, a third conductor layer 230, a fourth conductor layer 330, and a fifth conductor layer 430.

The first resin insulating layer 20 is formed on the insulating layer 4 and the conductor layer 10. The first resin insulating layer 20 has a first surface 22 (upper surface in the drawing) and a second surface 24 (lower surface in the drawing) on the opposite side with respect to the first surface 22. The second surface 24 of the first resin insulating layer 20 faces the conductor layer 10. The first resin insulating layer 20 has the first opening 26 that exposes the conductor layer 10. In FIG. 1, the first opening 26 exposes the pad 14. A diameter of a bottom part of the first opening 26 is 20 μm or more and 50 μm or less. The bottom part of the first opening 26 exposes the conductor layer 10. The first resin insulating layer 20 is formed of a resin 80 and a large number of inorganic particles 90 dispersed in the resin 80. The resin 80 is an epoxy resin. Examples of the resin include a thermosetting resin and a photocurable resin. Examples of the inorganic particles 90 include silica particles and alumina particles. The inorganic particles 90 have an average particle size of 0.5 μm or less. An amount of the inorganic particles 90 in the first resin insulating layer 20 is 75 wt % or more.

The build-up layer 500 further has via conductors that respectively penetrate the resin insulating layers (20, 120, 220, 320, 420). The via conductor that penetrates the first resin insulating layer 20 is a first via conductor 40. The via conductor that penetrates the second resin insulating layer 120 is a second via conductor 140. The via conductor that penetrates the third resin insulating layer 220 is a third via conductor 240. The via conductor that penetrates the fourth resin insulating layer 320 is a fourth via conductor 340. The via conductor that penetrates the fifth resin insulating layer 420 is a fifth via conductor 440. The first via conductor 40 is formed in the first opening 26 and connects the conductor layer 10 and the first conductor layer 30. The second via conductor 140 is formed in the second opening 126 and connects the first conductor layer 30 and the second conductor layer 130. The third via conductor 240 is formed in the third opening 226 and connects the second conductor layer 130 and the third conductor layer 230. The fourth via conductor 340 is formed in the fourth opening 326 and connects the third conductor layer 230 and the fourth conductor layer 330. The fifth via conductor 440 is formed in the fifth opening 426 and connects the fourth conductor layer 330 and the fifth conductor layer 430. The second via conductor 140, the third via conductor 240, the fourth via conductor 340, and the fifth via conductor 440 are laminated directly on the first via conductor 40. The first via conductor 40, the second via conductor 140, the third via conductor 240, the fourth via conductor 340, and the fifth via conductor 440 form a stacked via.

The first conductor layer 30 is formed on the first surface 22 of the first resin insulating layer 20. The first conductor layer 30 includes a solid pattern 32 and a land 34. Although not illustrated in the drawings, the first conductor layer 30 also includes conductor circuits other than the solid pattern 32 and the land 34. The solid pattern 32 is a power supply circuit or a ground circuit. The solid pattern 32 has a first width (W1). The solid pattern 32 has a smallest width in the first conductor layer.

The first conductor layer 30 is mainly formed of copper. The first conductor layer is formed of a seed layer (for example, an electroless copper plating layer) (30a) on the first surface 22 and an electrolytic plating layer (for example, an electrolytic copper plating layer) (30b) on the seed layer (30a). The seed layer (30a) is an electroless plating layer formed by electroless plating. The seed layer (30a) forming the first conductor layer can be referred to as a first seed layer. The electrolytic plating layer (30b) forming the first conductor layer can be referred to as a first electrolytic plating layer.

As illustrated in FIGS. 1 and 2A, the first via conductor 40 is formed in the first opening 26. The first via conductor 40 connects the conductor layer 10 and the first conductor layer 30. The first via conductor 40 connects the pad 14 and the land 34. The first via conductor 40 is formed of a seed layer (30a) and an electrolytic plating layer (30b) on the seed layer (30a). The seed layer (30a) that forms the first via conductor 40 and the seed layer (30a) that forms the first conductor layer 30 are common. The electrolytic plating layer (30b) that forms the first via conductor 40 and the electrolytic plating layer (30b) that forms the first conductor layer 30 are common.

As illustrated in FIGS. 2A and 2B, the first conductor layer 30 and the first via conductor 40 have voids (B). The voids (B) exist in at least one of the inside of the seed layer (30a) (first location), a boundary portion between the seed layer (30a) and the electrolytic plating layer (30b) (second location), and a connecting portion between the conductor layer 10 and the first via conductor 40 (third location). The second location includes an interface between the electrolytic plating layer (30b) (FIG. 2A) and the seed layer (30a) (FIG. 2A) that is in contact with the electrolytic plating layer (30b) and an interface between the seed layer (30a) (FIG. 2B) and the electrolytic plating layer (30b) (FIG. 2B) that is in contact with the seed layer (30a). The third location includes a boundary portion between the seed layer (30a) and the conductor layer 10. The third location includes an interface between the conductor layer 10 (FIG. 2A) and the seed layer (30a) (FIG. 2A) that is in contact with the conductor layer 10 and an interface between the seed layer (30a) (FIG. 2B) and the conductor layer 10 (FIG. 2B) that is in contact with the seed layer (30a). The voids (B) exist in the first location. In this case, the voids (B) preferably do not exist in the second location and the third location. Or the voids (B) exist in the second location. In this case, the voids (B) preferably do not exist in the first location and the third location. Or the voids (B) exist in the third location. In this case, the voids (B) preferably do not exist in the first location and the second location. Or the voids (B) exist in the first location and the second location. In this case, the voids (B) preferably do not exist in the third location. Or the voids (B) exist in the first location and the third location. In this case, the voids (B) preferably do not exist in the second location. Or the voids (B) exist in the second location and the third location. In this case, the voids (B) preferably do not exist in the first location. Or, the voids (B) exist in the first location, the second location, and the third location.

As illustrated in FIG. 1, the second resin insulating layer 120 is formed on the first surface 22 of the first resin insulating layer 20 and on the first conductor layer 30. The second resin insulating layer 120 has a third surface 122 (upper surface in the drawing) and a fourth surface 124 (lower surface in the drawing) on the opposite side with respect to the third surface 122. The fourth surface 124 of the second resin insulating layer 120 faces the first conductor layer 30. The second resin insulating layer 120 has the second opening 126 that exposes the first conductor layer 30. In FIG. 1, the second opening 126 exposes the land 34. A diameter of a bottom part of the second opening 126 is 20 μm or more and 50 μm or less. The bottom part of the second opening 126 exposes the land 34. The second resin insulating layer 120 is formed of a resin 80 and a large number of inorganic particles 90. The resin 80 and the inorganic particles 90 are similar to those in the first resin insulating layer 20.

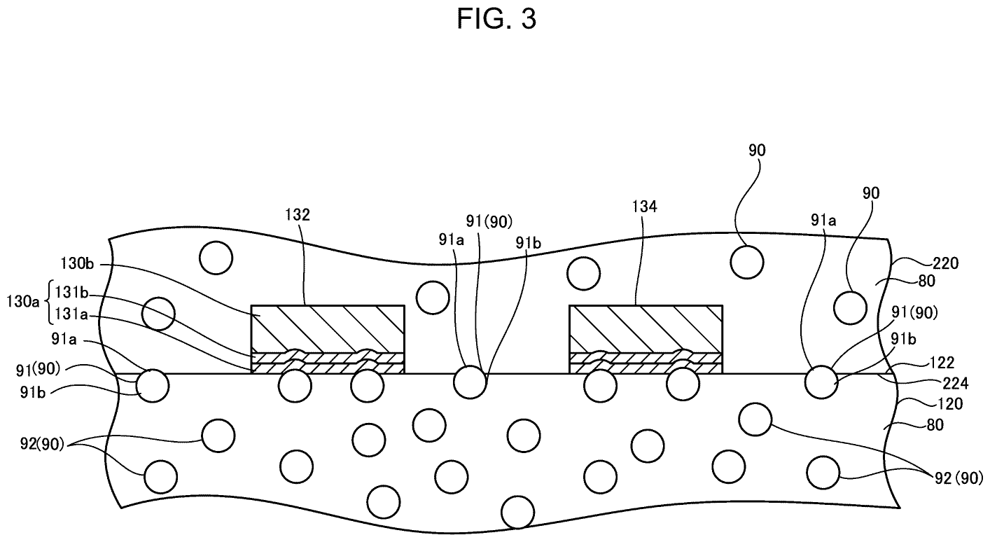

As illustrated in FIGS. 1 and 3, the inorganic particles 90 in the second resin insulating layer 120 include first inorganic particles 91 that are partially embedded in the resin 80 and second inorganic particles 92 that are embedded in the resin 80. The first inorganic particles 91 and the second inorganic particles 92 have spherical shapes. As illustrated in FIG. 3, the first inorganic particles 91 are each formed of a first portion (91a) protruding from the resin 80 and a second portion (91b) embedded in the resin 80. The third surface 122 of the second resin insulating layer 120 is formed by an upper surface of the resin 80 and exposed surfaces of the first portions (91a) exposed from the upper surface of the resin 80.

A ratio (R) of a volume of each of the first portions (91a) to a volume of each of the first inorganic particles 91 ((the volume of each of the first portions)/(the volume of each of the first particles)) is greater than 0 and less than or equal to 0.4. The ratio (R) is preferably 0.2 or less. The ratio (R) is more preferably 0.1 or less. The ratio (R) is most preferably 0.05 or less. When the first portions (91a) protrude from the resin 80, the third surface 122 of the second resin insulating layer 120 has a slight unevenness. However, the upper surface of the resin 80 is not roughened. Therefore, the third surface 122 has substantially no recesses. The third surface 122 has an arithmetic mean roughness (Ra) of less than 0.08 The roughness (Ra) of the third surface 122 is preferably 0.05 μm or less. The roughness (Ra) of the third surface 122 is more preferably 0.03 μm or less.

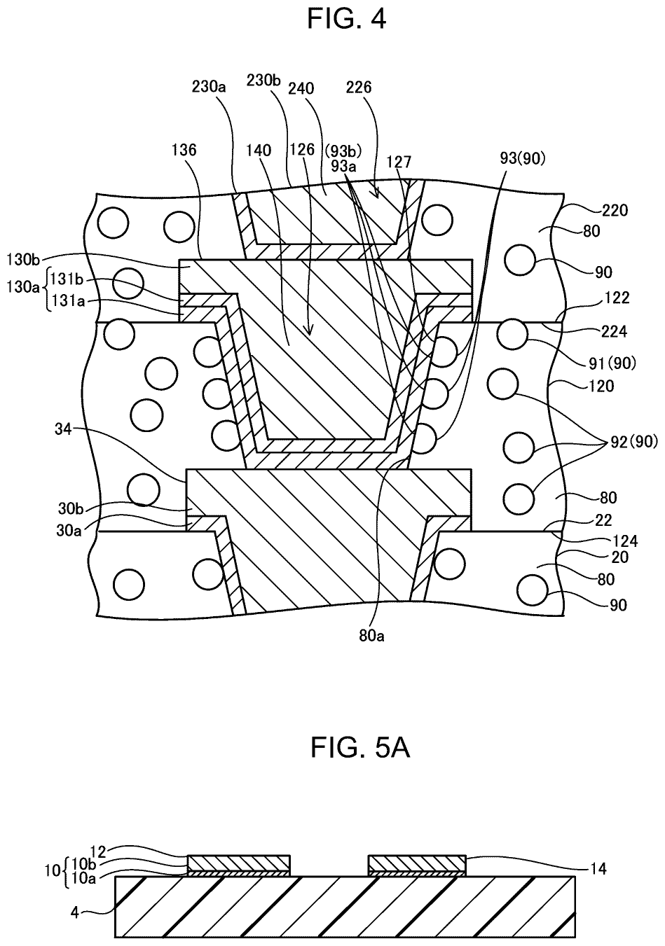

As illustrated in FIGS. 1 and 4, the inorganic particles 90 in the second resin insulating layer 120 further include third inorganic particles 93 that form an inner wall surface 127 of the second opening 126. The third inorganic particles 93 each have a shape obtained by cutting a sphere with a plane. The third inorganic particles 93 each have a shape obtained by cutting a second inorganic particle 92 with a plane. The third inorganic particles 93 and the second inorganic particles 92 are different in shape. The third inorganic particles 93 each have a flat part (93a). The flat parts (93a) form the inner wall surface 127. The inner wall surface 127 is formed of the resin 80 and the flat parts (93a). The flat parts (93a) and a surface of the resin 80 that forms the inner wall surface 127 form substantially a common surface. No unevenness is formed on the resin 80 that forms the inner wall surface 127. The surface of the resin 80 that forms the inner wall surface 127 is substantially smooth. No unevenness is formed on exposed surfaces of the flat parts (93a) (surfaces that form the inner wall surface 127). The exposed surfaces of the flat parts (93a) are smooth. The inner wall surface 127 is formed smooth. The inner wall surface 127 has an arithmetic mean roughness (Ra) of 1.0 μm or less.

As illustrated in FIG. 1, the second conductor layer 130 is formed on the third surface 122 of the second resin insulating layer 120. The second conductor layer 130 includes a first signal wiring 132, a second signal wiring 134, and a land 136. Although not illustrated in the drawing, the second conductor layer 130 also includes conductor circuits other than the first signal wiring 132, the second signal wiring 134, and the land 136. The first signal wiring 132 and the second signal wiring 134 form a pair wiring. The first signal wiring 132 and the second signal wiring 134 each have a smallest width in the second conductor layer 130. The first signal wiring 132 and the second signal wiring 134 each have a second width (W2). The second width (W2) is smaller than the first width (W1) (see FIG. 1). The first width (W1) is larger than the second width (W2).

The second conductor layer 130 is mainly formed of copper. The second conductor layer 130 is formed of a seed layer (130a) on the third surface 122 and an electrolytic plating layer (130b) on the seed layer (130a). The seed layer (130a) is a sputtering layer. The seed layer (130a) is formed of a first layer (131a) on the third surface 122 and a second layer (131b) on the first layer (131a). The seed layer (130a) has a thickness of less than 0.5 The first layer (131a) is formed of an alloy (copper alloy) containing copper and a specific base metal. The specific base metal is a base metal other than copper. The specific base metal is, for example, aluminum. The second layer (131b) is formed of copper. The electrolytic plating layer (130b) is formed of copper. The first layer (131a) is in contact with the third surface 122. The seed layer (130a) forming the second conductor layer 130 can be referred to as a second seed layer. The electrolytic plating layer (130b) forming the second conductor layer 130 can be referred to as a second electrolytic plating layer.

A content of copper in the copper alloy forming the first layer (131a) is greater than 90 at %. The content of copper in the copper alloy of the first layer (131a) is less than 99 at %. The content of copper in the copper alloy is 98 at % or less. A content of copper forming the second layer (131b) is 99.9 at % or more. The content of copper in the second layer (131b) is preferably 99.95 at % or more.

No voids exist in a boundary portion between the seed layer (130a) formed by sputtering and the electrolytic plating layer (130b) formed by electrolytic plating. No voids exist in the seed layer (130a) formed by sputtering. No voids exist in a boundary portion between the first layer (131a) formed by sputtering and the second layer (131b) formed by sputtering.

The second via conductor 140 is formed in the second opening 126. The second via conductor 140 connects the first conductor layer 30 and the second conductor layer 130. The second via conductor 140 connects the land 34 and the land 136. The second via conductor 140 is formed of a seed layer (130a) and an electrolytic plating layer (130b) on the seed layer (130a). The seed layer (130a) that forms the second via conductor 140 and the seed layer (130a) that forms the second conductor layer 130 are common. The electrolytic plating layer (130b) that forms the second via conductor 140 and the electrolytic plating layer (130b) that forms the second conductor layer 130 are common. The first layer (131a) is in contact with the inner wall surface 127. The seed layer (130a) that forms the second conductor layer 130 and the second via conductor 140 does not contain voids. No voids exist in a second connecting portion between the first conductor layer 30 (for example, the land 34) exposed by the second opening 126 and the second via conductor 140. The second connecting portion includes the inside of the seed layer (130a) on the first conductor layer 30 exposed by the second opening 126, a boundary portion between the first conductor layer 30 exposed by the second opening 126 and the seed layer (130a) on the first conductor layer 30, and a boundary portion between the seed layer (130a) on the first conductor layer 30 exposed by the second opening 126 and the electrolytic plating layer (130b) on the seed layer (130a). No voids exist in a boundary portion between a conductor layer (for example, the first conductor layer 30) and a seed layer (for example, the seed layer (130a)) formed by sputtering on the conductor layer. No voids exist in a boundary portion between a pad (for example, a portion of a conductor layer exposed at a bottom part of an opening for a via conductor) and a seed layer formed by sputtering on the pad. The pad and the seed layer formed by sputtering on the pad are in contact with each other. The seed layer formed by sputtering on the pad forms a via conductor.

The third resin insulating layer 220 is formed on the third surface 122 of the second resin insulating layer 120 and on the second conductor layer 130. The third resin insulating layer 220 has a fifth surface 222 (upper surface in the drawing) and a sixth surface 224 (lower surface in the drawing) on the opposite side with respect to the fifth surface 222. The sixth surface 224 of the third resin insulating layer 220 faces the second conductor layer 130. The third resin insulating layer 220 has the third opening 226 that exposes the second conductor layer 130. In FIG. 1, the third opening 226 exposes the land 136. A diameter of a bottom part of the third opening 226 is 20 μm or more and 50 μm or less. The bottom part of the third opening 226 exposes the land 136. The third resin insulating layer 220 is formed of a resin 80 and a large number of inorganic particles 90. The resin 80 and the inorganic particles 90 are similar to those in the first resin insulating layer 20.

The third conductor layer 230 is formed on the fifth surface 222 of the third resin insulating layer 220. The third conductor layer 230 includes a solid pattern 232 and a land 234. Although not illustrated in the drawings, the third conductor layer 230 also includes conductor circuits other than the solid pattern 232 and the land 234. The solid pattern 232 is a power supply circuit or a ground circuit. A seed layer (230a) forming the third conductor layer 230 can be referred to as a third seed layer. An electrolytic plating layer (230b) forming the third conductor layer 230 can be referred to as a third electrolytic plating layer.

The third conductor layer 230 is mainly formed of copper. The third conductor layer 230 is formed of the seed layer (230a) on the fifth surface 222 and the electrolytic plating layer (230b) on the seed layer (230a). The seed layer (230a) is an electroless plating layer. The seed layer (230a) is similar to the seed layer (30a) of the first conductor layer 30.

The third via conductor 240 is formed in the third opening 226. The third via conductor 240 connects the second conductor layer 130 and the third conductor layer 230. The third via conductor 240 connects the land 136 and the land 234. The third via conductor 240 is formed of a seed layer (230a) and an electrolytic plating layer (230b) on the seed layer (230a). The seed layer (230a) that forms the third via conductor 240 and the seed layer (230a) that forms the third conductor layer 230 are common. The electrolytic plating layer (230b) that forms the third via conductor 240 and the electrolytic plating layer (230b) that forms the third conductor layer 230 are common.

Similar to the first conductor layer 30, the third conductor layer 230 has voids. Similar to the first via conductor 40, the third via conductor 240 has voids. The voids are not illustrated in the drawings. The voids are similar to the voids (B) illustrated in FIGS. 2A and 2B.

The fourth resin insulating layer 320 is formed on the fifth surface 222 of the third resin insulating layer 220 and on the third conductor layer 230. The fourth resin insulating layer 320 has a seventh surface 322 (upper surface in the drawing) and an eighth surface 324 (lower surface in the drawing). The eighth surface 324 faces the third conductor layer 230. The fourth resin insulating layer 320 has the fourth opening 326 that exposes the third conductor layer 230. A bottom part of the fourth opening 326 exposes the land 234. A diameter of the bottom part of the fourth opening 326 is 20 μm or more and 50 μm or less. The bottom part of the fourth opening 326 exposes the land 234. The fourth resin insulating layer 320 is formed of a resin 80 and a large number of inorganic particles 90. The resin 80 and the inorganic particles 90 are similar to those in the second resin insulating layer 120.

Similar to the second resin insulating layer 120, the inorganic particles 90 in the fourth resin insulating layer 320 include first inorganic particles 91 that are partially embedded in the resin 80 and second inorganic particles 92 that are embedded in the resin 80. The first inorganic particles 91 and the second inorganic particles 92 are similar to the first inorganic particles 91 and the second inorganic particles 92 of FIG. 3. The seventh surface 322 of the fourth resin insulating layer 320 is formed by an upper surface of the resin 80 and exposed surfaces of the first portions (91a) (see FIG. 3) exposed from the upper surface of the resin 80.

Similar to the second resin insulating layer 120, the inorganic particles 90 in the fourth resin insulating layer 320 further include third inorganic particles 93 that form an inner wall surface 327 of the fourth opening 326. The third inorganic particles 93 are similar to the third inorganic particles 93 of FIG. 4. The third inorganic particles 93 each have a flat part (93a). The flat parts (93a) form the inner wall surface 327. The inner wall surface 327 is formed of the resin 80 and the flat parts (93a). The flat parts (93a) and a surface of the resin 80 that forms the inner wall surface 327 form substantially a common surface. No unevenness is formed on the resin 80 that forms the inner wall surface 327. The surface of the resin 80 that forms the inner wall surface 327 is substantially smooth. No unevenness is formed on exposed surfaces of the flat parts (93a) (surfaces that form the inner wall surface 327). The exposed surfaces of the flat parts (93a) are smooth. The inner wall surface 327 is formed smooth. The inner wall surface 327 has an arithmetic mean roughness (Ra) of 1.0 μm or less.

The fourth conductor layer 330 is formed on the seventh surface 322 of the fourth resin insulating layer 320. The fourth conductor layer 330 includes a third signal wiring 332, a fourth signal wiring 334, and a land 336. Although not illustrated in the drawings, the fourth conductor layer 330 also includes conductor circuits other than the third signal wiring 332, the fourth signal wiring 334 and the land 336. The third signal wiring 332 and the fourth signal wiring 334 form a pair wiring.

The fourth conductor layer 330 is mainly formed of copper. The fourth conductor layer 330 is formed of a seed layer (330a) on the seventh surface 322 and an electrolytic plating layer (330b) on the seed layer (330a). The seed layer (330a) is a sputtering layer. The seed layer (330a) is formed of a first layer (331a) on the seventh surface 322 and a second layer (331b) on the first layer (331a). The first layer (331a) is in contact with the seventh surface 322. The seed layer (330a) is similar to the seed layer (130a) of the second conductor layer 130.

The fourth via conductor 340 is formed in the fourth opening 326 The fourth via conductor 340 connects the third conductor layer 230 and the fourth conductor layer 330. The fourth via conductor 340 connects the land 234 and the land 336. The fourth via conductor 340 is formed of a seed layer (330a) and an electrolytic plating layer (330b) on the seed layer (330a). The seed layer (330a) that forms the fourth via conductor 340 and the seed layer (330a) that forms the fourth conductor layer 330 are common. The electrolytic plating layer (330b) that forms the fourth via conductor 340 and the electrolytic plating layer (330b) that forms the fourth conductor layer 330 are common. The first layer (331a) is in contact with the inner wall surface 327. The seed layer (330a) that forms the fourth conductor layer 330 and the fourth via conductor 340 does not have voids.

The fifth resin insulating layer 420 is formed on the seventh surface 322 of the fourth resin insulating layer 320 and on the fourth conductor layer 330. The fifth resin insulating layer 420 has a ninth surface 422 (upper surface in the drawing) and a tenth surface 424 (lower surface in the drawing) on the opposite side with respect to the ninth surface 422. The tenth surface 424 of the fifth resin insulating layer 420 faces the fourth conductor layer 330. The fifth resin insulating layer 420 has the fifth opening 426 that exposes the fourth conductor layer 330. A bottom part of the fifth opening 426 exposes the land 336. A diameter of the bottom part of the fifth opening 426 is 20 μm or more and 50 μm or less. The bottom part of the fifth opening 426 exposes the land 336. The fifth resin insulating layer 420 is formed of a resin 80 and a large number of inorganic particles 90. The resin 80 and the inorganic particles 90 are similar to those in the first resin insulating layer 20.

The fifth conductor layer 430 is formed on the ninth surface 422 of the fifth resin insulating layer 420. The fifth conductor layer 430 includes a solid pattern 432 and a land 434. Although not illustrated in the drawings, the fifth conductor layer 430 also includes conductor circuits other than the solid pattern 432 and the land 434. The solid pattern 432 is a power supply circuit or a ground circuit.

The fifth conductor layer 430 is mainly formed of copper. The fifth conductor layer 430 is formed of a seed layer (430a) on the ninth surface 422 and an electrolytic plating layer (430b) on the seed layer (430a). The seed layer (430a) is an electroless plating layer. The seed layer (430a) is similar to the seed layer (30a) of the first conductor layer 30.

Although not illustrated in the drawings, each side of the printed wiring board 2 has a length of 50 mm or more. The length of each side is preferably 100 mm or more. The length of each side is 250 mm or less.

### Method for Manufacturing Printed Wiring Board

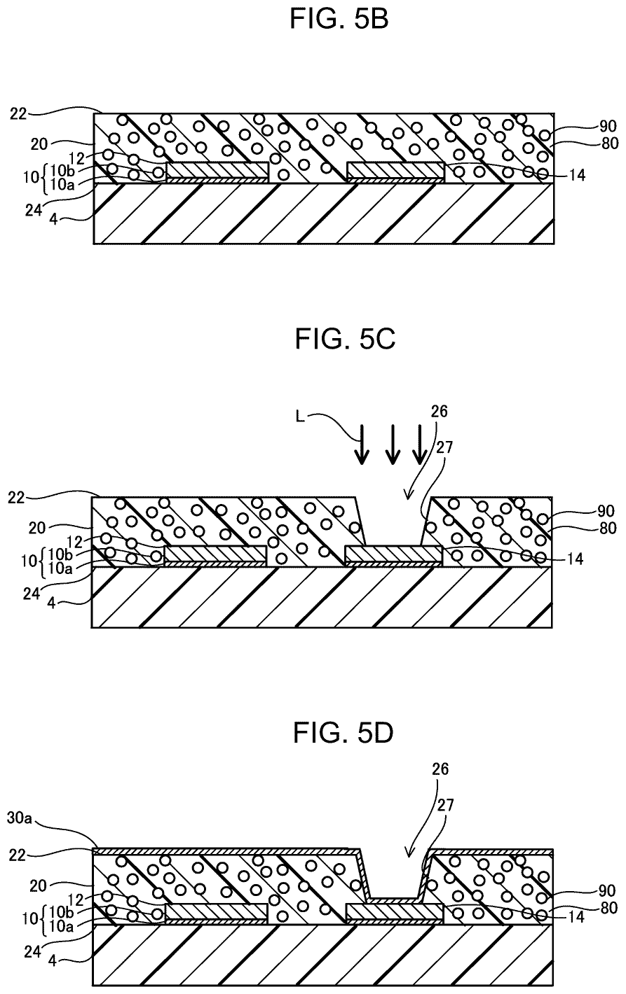

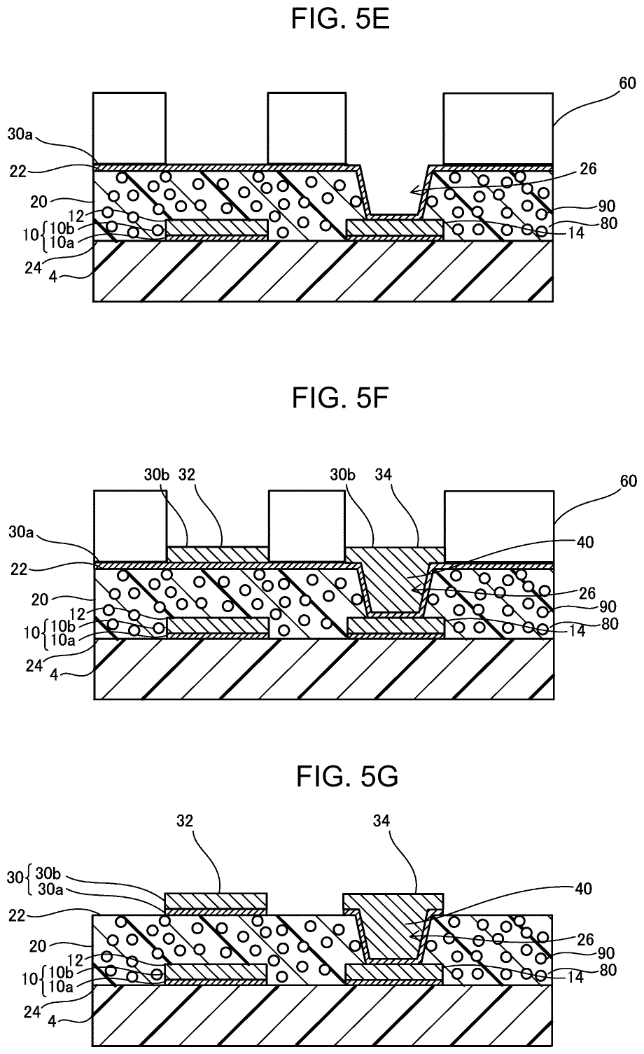

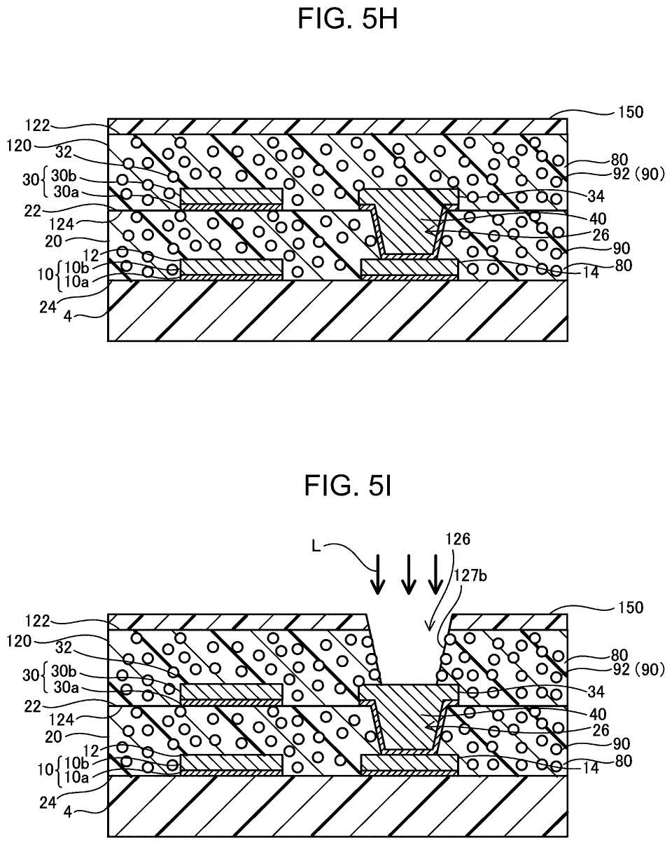

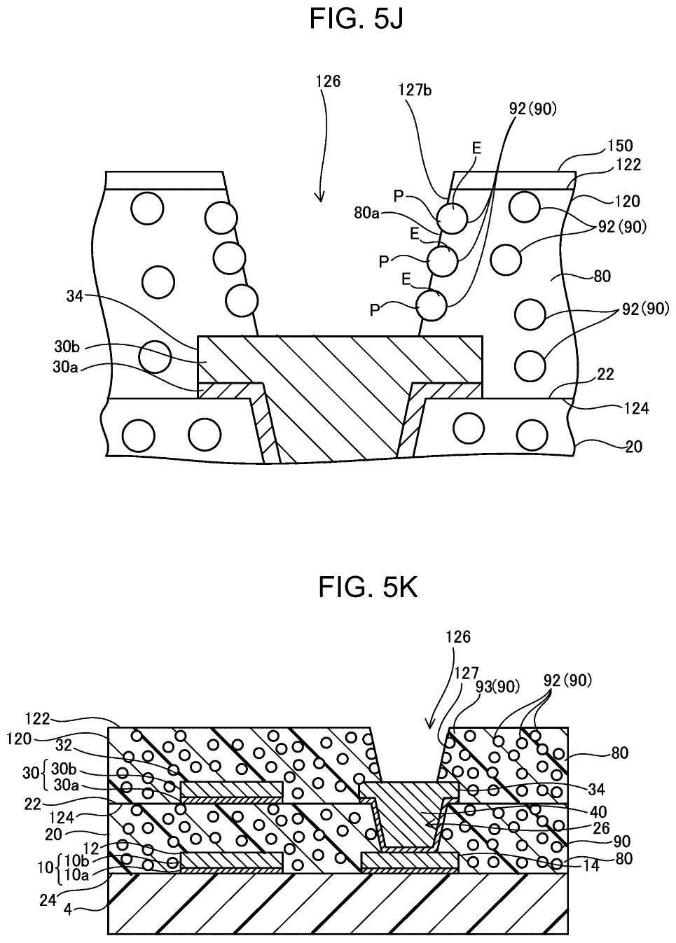

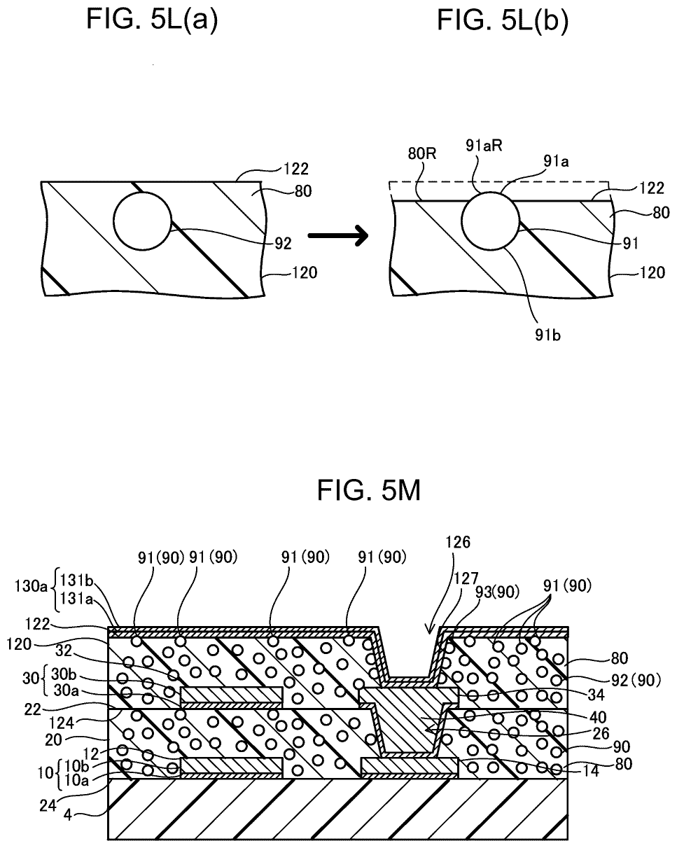

FIGS. 5A-5M illustrate a method for manufacturing the printed wiring board 2 of the embodiment. FIGS. 5A-5I, 5K, and 5M are cross-sectional views. FIGS. 5J and 5L are enlarged cross-sectional views. FIG. 5A illustrates the insulating layer 4 and the conductor layer 10 formed on the insulating layer 4. The conductor layer 10 is formed using a semi-additive method. The seed layer (10a) is formed by electroless plating. The electrolytic plating layer (10b) is formed by electrolytic plating. In a modified example, the seed layer (10a) is formed by sputtering.

As illustrated in FIG. 5B, the first resin insulating layer 20 is formed on the insulating layer 4 and the conductor layer 10. The second surface 24 of the first resin insulating layer 20 faces an upper surface of the insulating layer 4. The first resin insulating layer 20 has the resin 80 and the inorganic particles 90 (the second inorganic particles 92). The inorganic particles 90 are embedded in the resin 80.

As illustrated in FIG. 5C, laser (L) is irradiated from above the first surface 22. The laser (L) penetrates the first resin insulating layer 20. The first opening 26 for the first via conductor 40 reaching the pad 14 is formed. The laser (L) is, for example, UV laser, or CO2 laser. The first opening 26 exposes the pad 14. By irradiating the laser (L) to the first resin insulating layer 20, some of the second inorganic particles 92 embedded in the resin 80 are exposed on the inner wall surface 27 of the first opening 26. No treatment for smoothing the inner wall surface 27 is performed. The inner wall surface 27 has unevenness. The first resin insulating layer 20 does not have the third inorganic particles 93.

The inside of the first opening 26 is cleaned. By cleaning the inside of the first opening 26, resin residues generated when the first opening 26 is formed are removed. The cleaning of the inside of the first opening 26 is performed with potassium permanganate. That is, the cleaning is performed with a wet process. The cleaning includes a desmear treatment.

As illustrated in FIG. 5D, the seed layer (30a) is formed on the first surface 22 of the first resin insulating layer 20 and on the inner wall surface 27 and the pad 14, which are exposed from the first opening 26. The seed layer (30a) is formed by electroless plating. The formation of the seed layer (30a) is performed with a wet process. When the seed layer (30a) is formed by electroless plating involving gas generation, the generated gas is likely to be absorbed into the printed wiring board 2 of the embodiment. An example of the seed layer (30a) is an electroless plating layer formed by electroless plating involving gas generation. For example, the gas is absorbed into at least one of the first location, the second location, and the third location. It is thought that when the gas is absorbed into the printed wiring board 2 of the embodiment, the gas is a cause of voids. An example of the gas is a hydrogen gas. For example, the seed layer (30a) is formed using a Rochelle salt bath using a Rochelle salt as a complexing agent. It is thought that the gas embrittles a seed layer formed of an electroless plating layer (for example, an electroless copper plating layer). Or it is thought that the gas embrittles a conductor layer including a seed layer formed of an electroless plating layer. The electroless plating layer is formed on the inner wall surface 27 having unevenness. The electroless plating layer is formed on the inner wall surface 27 that does not have the third inorganic particles 93.

After the formation of the seed layer (30a), heat is applied to the intermediate substrate. The intermediate substrate is subjected to a heat treatment (annealing). Examples of conditions for the heat treatment of the embodiment are as follows. Heating temperature (T) is 120° C., and heating time is 2 hours. When the intermediate substrate is heated under these heating conditions, the gas absorbed in the intermediate substrate is unlikely to be completely removed from the intermediate substrate. There is no need to perform the heat treatment immediately after the formation of the seed layer (30a). When the gas is not completely removed, voids are formed in at least one location among the inside of the seed layer (30a) (first location), the upper surface of the seed layer (30a) (second location), and the lower surface of the seed layer (30a) (third location). The second location includes a boundary portion between the seed layer (30a) and the electrolytic plating layer (30b). The third location includes a connecting portion between the seed layer (30a) and the pad 14.

### Heating Conditions of Reference Example

Heating conditions of a reference example are as follows. T is heating temperature (° C.) and t is heating time (hours). The heating conditions of the reference example are such that the following two formulas (Formula 1 and Formula 2) are both satisfied.

7×10^{6<T}3×t<18×10⁶ Formula 1:

60° C.≤T≤180° C. Formula 2:

For example, the heating temperature (T) is 100° C. and the heating time (t) is 10 hours. When the printed wiring board is subjected to the heating conditions of the reference example, no voids are observed in the first location, the second location, and the third location. When a printed wiring board is subjected to the heating conditions of the reference example, such a printed wiring board is a printed wiring board of the reference example.

As illustrated in FIG. 5E, a plating resist 60 is formed on the seed layer (30a). The plating resist 60 has openings for forming the solid pattern 32 and the land 34 (FIG. 1). As illustrated in FIG. 5F, the electrolytic plating layer (30b) is formed on the seed layer (30a) exposed from the plating resist 60. The electrolytic plating layer (30b) is formed of copper. In this case, the electrolytic plating layer (30b) is an electrolytic copper plating layer. The electrolytic plating layer (30b) fills the first opening 26. The solid pattern 32 and the land 34 are formed by the seed layer (30a) and the electrolytic plating layer (30b) on the first surface 22. The first conductor layer 30 is formed. The first via conductor 40 is formed by the seed layer (30a) and the electrolytic plating film (30b) in the first opening 26. The first via conductor 40 connects the pad 14 and the land 34.

The printed wiring board 2 of the embodiment has voids (B) in any one of the first location, the second location, and the third location. In contrast, the printed wiring board of the reference example does not have voids (B) in any one of the first location, the second location, and the third location. When voids (B) exist in a conductor layer, resistance of the conductor layer is high. Or, strength of the conductor layer is low. It is thought that when there are voids (B) in a conductor layer, cracks occur from the voids (B) in the conductor layer. It is thought that when voids (B) exist in a boundary portion (for example, a boundary between an electroless plating layer and an electrolytic plating layer), peeling occurs from the boundary portion. For example, an electrolytic plated layer peels off from an electroless plated layer. Or a via conductor peels off from a pad. Therefore, it is thought that the printed wiring board of the reference example is being used in the market.

The plating resist 60 is removed. As illustrated in FIG. 5G, the seed layer (30a) exposed from the electrolytic plating layer (30b) is removed. The seed layer (30a) is removed by wet etching. An etching solution used in the wet etching is an aqueous solution containing hydrogen peroxide and sulfuric acid. The first conductor layer 30 and the first via conductor 40 are formed at the same time.

As illustrated in FIG. 5H, the second resin insulating layer 120 and a protective film 150 are formed on the first surface 22 of the first resin insulating layer 20 and the first conductor layer 30. The fourth surface 124 of the second resin insulating layer 120 faces the first surface 22 of the first resin insulating layer 20. The protective film 150 is formed on the third surface 122 of the second resin insulating layer 120. The second resin insulating layer 120 has the resin 80 and the inorganic particles 90 (the second inorganic particles 92). The inorganic particles 90 are embedded in the resin 80.

The protective film 150 completely covers the third surface 122 of the second resin insulating layer 120. An example of the protective film 150 is a film formed of polyethylene terephthalate (PET). A release agent is formed between the protective film 150 and the second resin insulating layer 120.

As illustrated in FIG. 5I, laser (L) is irradiated from above the protective film 150. The laser (L) penetrates the protective film 150 and the second resin insulating layer 120 at the same time. The second opening 126 for the second via conductor 140 reaching the land 34 of the first conductor layer 30 is formed. The laser (L) is, for example, UV laser or CO2 laser. The second opening 126 exposes the land 34. When the second opening 126 is formed, the third surface 122 is covered by the protective film 150. Therefore, when the second opening 126 is formed, even when the resin scatters, adherence of the resin to the third surface 122 is suppressed.

FIG. 5J illustrates an inner wall surface (127b) of the second opening 126 after the laser irradiation. The inner wall surface (127b) is formed of the resin 80 and the inorganic particles 90 protruding from the resin 80. In order to control a shape of the inner wall surface, the inner wall surface (127b) after the laser irradiation is treated. It is preferable to selectively remove the inorganic particles 90 protruding from the resin 80. As a result, the third inorganic particles 93 are formed from the inorganic particles 90. For example, the inorganic particles 90 protruding from the resin 80 are selectively removed by treating the inner wall surface (127b) after the laser irradiation with a chemical. Or the inorganic particles 90 protruding from the resin 80 are selectively removed by treating the inner wall surface (127b) after the laser irradiation with plasma. The selectively removing includes that an etching rate of the inorganic particles 90 is greater than an etching rate of the resin 80. For example, a difference in etching rate between the two is 10 or more times. Or the difference in etching rate between the two is 50 or more times. Or the difference in etching rate between the two is 100 or more times. By treating the inner wall surface (127b) after the laser irradiation, the third inorganic particles 93 having the flat parts (93a) (see FIG. 4) are obtained. By controlling conditions for treating the inner wall surface (127b) after the laser irradiation, a shape of the inner wall surface can be controlled. Examples of the conditions are a temperature, a concentration, a time, a type of gas, and a pressure. The etching rate of the inorganic particles 90 and the etching rate of the resin are controlled.

By irradiating the laser (L) to the second resin insulating layer 120, some of the second inorganic particles 92 embedded in the resin 80 form the inner wall surface (127b) after the laser irradiation. The second inorganic particles 92 forming the inner wall surface (127b) after the laser irradiation are each formed of a protruding portion (P) protruding from the resin 80 and a portion (E) embedded in the resin 80. The inner wall surface (127b) after the laser irradiation is treated. For example, the inner wall surface (127b) is treated with plasma of a gas containing tetrafluoromethane. The protruding portions (P) are selectively removed, and the inner wall surface 127 (FIGS. 1 and 4) of the embodiment is formed. The third inorganic particles 93 are formed from the second inorganic particles 92. By selectively removing the protruding portions (P), the third inorganic particles 93 having the flat parts (93a) are formed. The flat parts (93a) are flat surfaces. When the second inorganic particles 92 having spherical shapes are cut along a plane, the shapes of the third inorganic particles 93 are obtained. The inner wall surface 127 is formed of the flat parts (93a) and a surface (80a) of the resin 80. Exposed surfaces (93b) of the flat parts (93a) and the surface (80a) of the resin 80 are positioned substantially on the same plane. For example, when the seed layer (130a) is formed by sputtering on the inner wall surface (127b) illustrated in FIG. 5J, the protruding portions (P) inhibit growth of a sputtering film. For example, a continuous seed layer (130a) is not formed on the inner wall surface (127b). Or the seed layer (30a) is increased in thickness. A fine conductor circuit cannot be formed. In the embodiment, the projecting portions (P) are removed. The seed layer (130a) formed by sputtering can be reduced in thickness. Even when the seed layer (130a) formed by sputtering is thin, a continuous seed layer (130a) can be obtained. The seed layer (130a) has a thickness of 0.05 μm or more and less than 0.5 μm.

No unevenness is formed on the inner wall surface 127. The inner wall surface 127 is formed smooth. By controlling the conditions for treating the inner wall surface (127b) after the laser irradiation, a size of unevenness is controlled.

The inside of the second opening 126 is cleaned. By cleaning the inside of the second opening 126, resin residues generated when the second opening 126 is formed are removed. The cleaning of the inside of the second opening 126 is performed using plasma. That is, the cleaning is performed with a dry process. The cleaning includes a desmear treatment. The third surface 122 of the second resin insulating layer 120 is covered by the protective film 150, and thus, is not affected by the plasma. At this point, no unevenness is formed on the third surface 122 of the second resin insulating layer 120. The inorganic particles 90 are not exposed on the third surface 122. The third surface 122 is not roughened.

When treating the inner wall surface (127b) after the laser irradiation includes cleaning the inside of the second opening 126, cleaning the inside of the second opening 126 can be omitted.

As illustrated in FIG. 5K, after cleaning the inside of the second opening 126, the protective film 150 is removed from the second resin insulating layer 120. When treating the inner wall surface (127b) after the laser irradiation includes cleaning the inside of the second opening 126, the protective film 150 is removed from the second resin insulating layer 120 after treating the inner wall surface (127b) after the laser irradiation. When the inner wall surface (127b) after the laser irradiation is treated, the protective film 150 covers the third surface 122 of the second resin insulating layer 120.

After removing the protective film 150, the third surface 122 of the second resin insulating layer 120 is cleaned. The third surface 122 is dry etched. The dry etching is performed by sputtering using argon gas (argon sputtering). FIGS. 5L(a) and 5L(b) schematically illustrate the third surface 122 of the second resin insulating layer 120 before and after the dry etching. As illustrated in FIGS. 5L(a) and 5L(b), about 20 nm of the resin 80 forming the second resin insulating layer 120 is removed by the dry etching. For example, an adhesive used to adhere the protective film 150 to the second resin insulating layer 120 is removed. By the dry etching, the resin 80 is selectively removed.

The resin 80 is reduced in thickness. Some of the inorganic particles 90 (the second inorganic particles 92) are partially exposed from the upper surface of the resin 80 by the dry etching. The first inorganic particles 91 are obtained by exposing the second inorganic particles 92 embedded in the resin 80 from the upper surface of the resin 80. The first inorganic particles 91 are formed from the second inorganic particles 92. The first inorganic particles 91 and the second inorganic particles 92 have the same shape. Both have a spherical shape. As illustrated in FIG. 5L(b), the first inorganic particles 91 are each formed of a first portion (91a) protruding from the resin 80 and a second portion (91b) embedded in the resin 80. The third surface 122 of the second resin insulating layer 120 is formed by an upper surface (80R) of the resin 80 and exposed surfaces (91aR) of the first portions (91a) protruding from the upper surface (80R) of the resin 80. The exposed surfaces (91aR) of the first portions (91a) are exposed by the dry etching. The third surface 122 of the second resin insulating layer 120 is not roughened. Therefore, substantially no recesses are formed on the third surface 122.

The ratio (R) is calculated, for example, using the cross-sectional view of the first inorganic particles 91 illustrated in FIG. 5L(b). FIG. 5L(b) is obtained by cutting the second resin insulating layer 120 with a plane perpendicular to the upper surface (80R). In FIG. 5L(b), the second conductor layer 130 is omitted. The second conductor layer 130 is formed on the first inorganic particles 91 in FIG. 5L(b). The exposed surfaces (91aR) in FIG. 5L(b) are covered by the second conductor layer 130. Using FIG. 5L(b), a cross-sectional area (91aS) of the first portions (91a) is obtained. Similarly, a cross-sectional area (91S) of the first inorganic particles 91 is obtained. For example, the ratio (R) is represented by a ratio of the cross-sectional area (91aS) to the cross-sectional area (91S) ((the cross-sectional area (91aS) of the first portions (91a))/(the cross-sectional area (91S) of the first inorganic particles 91)). For example, 50 first inorganic particles 91 are observed when the ratio (R) is evaluated. Fifty first inorganic particles 91 satisfy the ratio (R).

As illustrated in FIG. 5M, the seed layer (130a) is formed on the third surface 122 of the second resin insulating layer 120. The seed layer (130a) is formed by sputtering. The formation of the seed layer (130a) is performed with a dry process. The first layer (131a) is formed on the third surface 122 by sputtering. At the same time, the first layer (131a) is formed by sputtering on the inner wall surface 127 and the land 34, which are exposed from the second opening 126. Substantially no recesses are formed on the third surface 122. Therefore, the first layer (131a) on the third surface 122 is formed substantially flat. After that, the second layer (131b) is formed by sputtering on the first layer (31a). The second layer (131b) is formed substantially flat. The first layer (131a) and the second layer (131b) are formed in vacuum. The seed layer (130a) is also formed on the upper surface of the land 34 exposed from the second opening 126 and on the inner wall surface 127 of the second opening 126. The first layer (131a) is formed of an alloy containing copper and a specific base metal (aluminum). The second layer (131b) is formed of copper. A seed layer formed by sputtering can be referred to as a sputtering layer. A sputtering layer is formed on the inner wall surface 127 including the flat parts (93a). A sputtering layer is formed on the inner wall surface 127 including the third inorganic particles 93.

The third surface 122 has no recesses. The inner wall surface 127 is formed smooth. Therefore, even when the sputtering layers (the first layer (131a) and the second layer (131b)) are thin, a continuous seed layer (130a) can be formed. As a result, fine wirings can be formed.

A plating resist is formed on the seed layer (130a). The plating resist has openings for forming the first signal wiring 132, the second signal wiring 134, and the land 136 (FIG. 1). When the third surface 122 has recesses, air caused by the recesses is likely to be trapped between the plating resist and the seed layer (130a). However, in the embodiment, the third surface 122 has substantially no recesses. Therefore, the seed layer (130a) on the third surface 122 is formed substantially flat. The seed layer (130a) has substantially no recesses. Air is unlikely to remain between the plating resist and the seed layer (130a). A contact area between the plating resist and the seed layer (130a) is large. Even when a width of the plating resist for forming a space between the first signal wiring 132 and the second signal wiring 134 is 10 μm or less, the plating resist is unlikely to peel off from an upper surface of the seed layer (130a). According to the embodiment, even when the width of the plating resist is 3 μm or more and 8 μm or less, the plating resist can be formed on the seed layer (130a). Even when the width of the plating resist is 6 μm or less, the plating resist is unlikely to peel off from the seed layer (130a).

The electrolytic plating layer (130b) is formed on the seed layer (130a) exposed from the plating resist. The electrolytic plating layer (130b) is formed of copper. The electrolytic plating layer (130b) fills the second opening 126. The first signal wiring 132, the second signal wiring 134, and the land 136 are formed by the seed layer (130a) and the electrolytic plating film (130b) on the third surface 122. The second conductor layer 130 is formed. The second via conductor 140 is formed by the seed layer (130a) and the electrolytic plating film (130b) in the second opening 126. The second via conductor 140 connects the land 34 and the land 136. The first signal wiring 132 and the second signal wiring 134 form a pair wiring.

The plating resist is removed. The seed layer (130a) exposed from the electrolytic plating layer (130b) is removed. The seed layer (130a) is removed by wet etching. An etching solution used in the wet etching is an aqueous solution containing hydrogen peroxide and sulfuric acid. By the wet etching, the first layer (131a) and the second layer (131b) are removed at the same time. The second conductor layer 130 and the second via conductor 140 are formed at the same time.

The third resin insulating layer 220, the third conductor layer 230, and the third via conductor 240 are formed. A method of forming the third resin insulating layer 220, the third conductor layer 230, and the third via conductor 240 is the same as the method of forming the first resin insulating layer 20, the first conductor layer 30, and the first via conductor 40.

The fourth resin insulating layer 320, the fourth conductor layer 330, and the fourth via conductor 340 are formed. A method of forming the fourth resin insulating layer 320, the fourth conductor layer 330, and the fourth via conductor 340 is the same as the method of forming the second resin insulating layer 120, the second conductor layer 130, and the second via conductor 140.

The fifth resin insulating layer 420, the fifth conductor layer 430, and the fifth via conductor 440 are formed. A method of forming the fifth resin insulating layer 420, the fifth conductor layer 430, and the fifth via conductor 440 is the same as the method of forming the first resin insulating layer 20, the first conductor layer 30, and the first via conductor 40. The printed wiring board 2 (FIG. 1) of the embodiment is obtained.

The printed wiring board 2 of the embodiment has a conductor layer (for example, the first conductor layer 30) that includes the seed layer (30a) formed by electroless plating and a conductor layer (for example, the second conductor layer 130) that includes the seed layer (130a) formed by sputtering. In the embodiment, not all the seed layers of the conductor layers are formed by sputtering. Therefore, even when a production process includes sputtering, productivity can be increased. Production cost can be suppressed.

As illustrated in FIGS. 2A and 2B, a conductor layer (for example, the first conductor layer 30) that includes a seed layer formed of an electroless plating layer (for example, an electroless copper plated layer) has voids in at least one location among the inside of the seed layer (30a) (first location) and a boundary portion between the seed layer (30a) and the electrolytic plating layer (30b) (second location). A connecting portion between a via conductor (for example, the first via conductor 40), which includes a seed layer formed of an electroless plating layer (for example, an electroless copper plating layer), and a pad has voids in at least one location among the inside of the seed layer (30a) (first location), a boundary portion between the seed layer (30a) and the electrolytic plating layer (30b) (second location), and a boundary portion between the pad 14 and the via conductor (for example, the first via conductor 40) (third location). The third location includes a boundary portion between the electroless plating layer, which forms the via conductor, and the pad. By adjusting the heating conditions of the heat treatment after the formation of the seed layer (for example, the seed layer (30a)) by electroless plating, voids (B) are formed in at least one of the first location, the second location, and the third location. On the other hand, for a conductor layer (for example, the second conductor layer 130) that includes a seed layer (for example, the seed layer (130a)) formed by sputtering, no voids exist in the inside of the seed layer (130a) (first location) and a boundary portion between the seed layer (130a) and the electrolytic plating layer (130b) (second location). No voids exist in a boundary portion between a via conductor (for example, the second via conductor 140) and a pad (third location). The third location includes a boundary portion between the sputtering layer, which forms the via conductor, and the pad.

Electroless plating and sputtering are different in principle. Therefore, it is difficult to make adhesion between an electroless plating layer and an electrolytic plating layer on the electroless plating layer (the former) and adhesion between a sputtering layer and an electrolytic plating layer on the sputtering layer (the latter) the same. It is difficult to make adhesion between a pad and an electroless plating layer on the pad (the former) and adhesion between a pad and a sputtering layer on the pad (the latter) the same. When the printed wiring board is used, the printed wiring board is subjected to stress repeatedly. When the latter is lower than the former, stress is likely to concentrate in a boundary portion between a sputtering layer and an electrolytic plating layer. Or stress tends is likely to concentrate in a boundary portion between a pad and a sputtering layer. Therefore, due to stress, the following problems are likely to occur. For example, peeling occurs between a sputtering layer and an electrolytic plating layer. Or, peeling occurs between a pad and a sputtering layer. Or connection resistance between a pad and a via conductor that includes a sputtering layer increases.

An electroless plating layer is formed in a liquid. Therefore, even when a surface to be plated has unevenness, an electroless plating layer is likely to follow the unevenness. Further, even when the surface to be plated has large recesses, the electroless plating layer is likely to be formed in the large recesses. In contrast, sputtering particles are likely to move straight. Therefore, when a surface to be sputtered has unevenness, it is thought that a sputtering layer has significant variation in thickness. Further, even when the surface to be sputtered has large recesses, the sputtering layer is unlikely to grow on walls or bottoms of the large recesses. The sputtering layer is formed on the surface to be sputtered. Therefore, the former is likely to be larger than the latter. However, in the embodiment, a conductor layer and a via conductor that include a seed layer (for example, the seed layer (30a)) formed by electroless plating have voids (B) in at least one of the first location, the second location, and the third location. Therefore, the former is likely to decrease. In contrast, a conductor layer and a via conductor that include a seed layer (for example, the seed layer (130a)) formed by sputtering do not have voids (B) in any one of the first location, the second location, and the third location. Therefore, the latter is unlikely to decrease. In the printed wiring board 2 of the embodiment, the former and the latter are substantially the same. Therefore, substantially the same stress acts on a first boundary portion (a boundary portion between an electroless plating layer and an electrolytic plating layer) and a third boundary portion (a boundary portion between a sputtering layer and an electrolytic plating layer). Substantially the same stress acts on a second boundary portion (a boundary portion between a pad and an electroless plating layer) and a fourth boundary portion (a boundary portion between a pad and a sputtering layer). Substantially the same stress acts on the first boundary portion, the second boundary portion, the third boundary portion, and the fourth boundary portion. Even when the printed wiring board 2 of the embodiment is subjected to stress repeatedly, peeling is unlikely to occur between a seed layer and an electrolytic plating layer. Peeling is unlikely to occur between a pad and a via conductor. Connection resistance between a pad and a via conductor is stable over a long period of time. A printed wiring board 2 with high connection reliability is provided.

### First Alternative Example of Embodiment

In a first alternative example, the first conductor layer 30 and the first via conductor 40 have voids in one or two locations among the inside of the seed layer (30a) (first location), a boundary portion between the seed layer (30a) and the electrolytic plating layer (30b) (second location), and a connecting portion between the pad 14 and the first via conductor 40. Similarly, the third conductor layer 230 and the third via conductor 240 have voids in one or two locations among the inside of the seed layer (230a) (first location), a boundary portion between the seed layer (230a) and the electrolytic plating layer (230b) (second location), and a connecting portion between the land 136 and the third via conductor 240 (third location).

### Second Alternative Example of Embodiment

In the printed wiring board 2 of the embodiment, the conductor layers (the first conductor layer 30, the third conductor layer 230 and the fifth conductor layer 430) that each include a seed layer formed by electroless plating and the conductor layers (the second conductor layer 130 and the fourth conductor layer 330) that each include a seed layer formed by sputtering are alternately provided. In a printed wiring board 2 of a second alternative example, conductor layers that each include a seed layer formed by electroless plating and conductor layers that each include a seed layer formed by sputtering are freely laminated. The conductor layers of the two types can be laminated in any order. For example, the first conductor layer 30 that includes the seed layer (30a) formed by electroless plating may be provided on the second conductor layer 130 that includes the seed layer (130a) formed by sputtering. An uppermost conductor layer preferably includes a seed layer formed by sputtering. The uppermost conductor layer is covered by a solder resist layer with openings. Bumps for mounting an electronic component are formed on the uppermost conductor layer exposed through the openings of the solder resist layer. The bumps are formed of solder. Or, the bumps are formed by plating.

The printed wiring boards 2 of the embodiment and the alternative examples each include multiple conductor circuits. An opening for a via conductor reaches a portion (first portion) of a conductor circuit. The first portion is exposed by a bottom part of the opening for a via conductor. The first portion can be referred to as a pad. When an opening for a via conductor reaches a land, a part of the land can be referred to as a pad. A part of the land is exposed by a bottom part of the opening for a via conductor.

When a conductor layer and a via conductor have voids (B), the voids (B) exist in at least one of the first location, the second location, and the third location.

Japanese Patent Application Laid-Open Publication No. 2000-124602 describes a method for manufacturing a printed wiring board including forming an opening for via hole formation in an interlayer resin insulating layer; and forming an alloy layer by sputtering on a surface of the interlayer insulating layer having the opening for via hole formation.

Sputtering is performed in vacuum. It is thought that when a printed wiring board including multiple conductor layers is formed, forming seed layers of all the conductor layers by sputtering affects productivity. It is thought that production cost increases.

A printed wiring board according to an embodiment of the present invention includes: a conductor layer that has a pad; a first resin insulating layer that has a first surface and a second surface on the opposite side with respect to the first surface and is laminated on the conductor layer such that the second surface faces the conductor layer; a first conductor layer that is formed on the first surface of the first resin insulating layer; a second resin insulating layer that has a third surface and a fourth surface on the opposite side with respect to the third surface and is laminated on the first conductor layer and the first resin insulating layer such that the fourth surface faces the first conductor layer; and a second conductor layer that is formed on the third surface of the second resin insulating layer. The first conductor layer includes a first seed layer formed by electroless plating and a first electrolytic plating layer formed on the first seed layer. The second conductor layer includes a second seed layer formed by sputtering and a second electrolytic plating layer formed on the second seed layer.

The printed wiring board according to an embodiment of the present invention includes the first conductor layer that includes the first seed layer formed by electroless plating, and the second conductor layer that includes the second seed layer formed by sputtering. Therefore, not all the seed layers of the conductor layers are formed by sputtering. Therefore, productivity of the printed wiring board is unlikely to decrease. Production cost can be suppressed.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a conductor layer including a pad;
a first resin insulating layer laminated on the conductor layer;
a first conductor layer formed on the first resin insulating layer and comprising a first seed layer and a first electrolytic plating layer formed on the first seed layer;
a second resin insulating layer laminated on the first resin insulating layer such that the second resin insulating layer is covering the first conductor layer; and
a second conductor layer formed on the second resin insulating layer and comprising a second seed layer and a second electrolytic plating layer formed on the second seed layer,
wherein the first conductor layer is formed such that the first seed layer is an electroless plating layer and the first electrolytic plating layer formed on the first seed layer, and the second conductor layer is formed such that a second seed layer is a sputtering layer and the second electrolytic plating layer formed on the second seed layer.

2. The printed wiring board according to claim 1, wherein the first conductor layer has voids in at least one of the first seed layer and a boundary portion between the first seed layer and the first electrolytic plating layer, and the second conductor layer does not have voids in the second seed layer and in a boundary portion between the second seed layer and the second electrolytic plating layer.

3. The printed wiring board according to claim 2, wherein the first conductor layer has voids in the first seed layer and in a boundary portion between the first seed layer and the first electrolytic plating layer.

4. The printed wiring board according to claim 1 further comprising:
a first via conductor formed in a first opening formed in the first resin insulating layer and comprising the first seed layer and the first electrolytic plating layer such that the first via conductor is connecting the first conductor layer and the pad in the conductor layer,
wherein the first via conductor is formed such that voids exist in a connecting portion between the pad and the first via conductor and that the voids in the connecting portion exist in at least one of the first seed layer, a boundary portion between the first seed layer and the first electrolytic plating layer in the connecting portion, and a boundary portion between the first seed layer and the pad, and the second conductor layer does not have voids in the second seed layer and in a boundary portion between the second seed layer and the second electrolytic plating layer.

5. The printed wiring board according to claim 4, wherein the first via conductor is formed such that the voids in the connecting portion between the pad and the first via conductor exist at least in the first seed layer and the boundary portion between the first seed layer and the first electrolytic plating layer in the connecting portion.

6. The printed wiring board according to claim 1, wherein the first conductor layer has a first conductor circuit having a first width such that the first width is a smallest width in the first conductor layer, the second conductor layer has a second conductor circuit having a second width such that the second width is a smallest width in the second conductor layer and that the first width of the first conductor circuit in the first conductor layer is larger than the second width of the second conductor circuit in the second conductor layer.

7. The printed wiring board according to claim 1, further comprising:
a third resin insulating layer formed on the second resin insulating layer such that the third resin insulating layer is covering the second conductor layer; and
a third conductor layer formed on the third resin insulating layer and comprising a third seed layer and a third electrolytic plating layer formed on the third seed layer,
wherein the third conductor layer is formed such that the third seed layer is an electroless plating layer and that the third conductor layer has voids in at least one of the third seed layer and a boundary portion between the third seed layer and the third electrolytic plating layer.

8. The printed wiring board according to claim 1, wherein the second resin insulating layer includes a resin and inorganic particles such that the inorganic particles include first inorganic particles partially embedded in the resin and second inorganic particles completely embedded in the resin, that each of the first inorganic particles has a first portion protruding from the resin and a second portion embedded in the resin, and that the second resin insulating layer has a surface including a surface of the resin and exposed surfaces of the first portions exposed from the surface of the resin.

9. The printed wiring board according to claim 8, wherein the second resin insulating layer is formed such that a ratio of a volume of the first portions to a volume of the first inorganic particles is greater than 0 and less than or equal to 0.4.

10. The printed wiring board according to claim 8, wherein the second resin insulating layer is formed such that the surface of the second resin insulating layer has an arithmetic mean roughness Ra of less than 0.08 μm.

11. The printed wiring board according to claim 8, further comprising:
a second via conductor formed in a second opening formed in the second resin insulating layer and comprising of the second seed layer and the second electrolytic plating layer such that the second via conductor is connecting the first conductor layer and the second conductor layer,
wherein the second resin insulating layer is formed such that the inorganic particles include third inorganic particles having flat parts forming an inner wall surface of the second opening.

12. The printed wiring board according to claim 11, wherein the second resin insulating layer is formed such that each of the third inorganic particles has a sphere shape with a cut plane.

13. The printed wiring board according to claim 12, wherein the second resin insulating layer is formed such that each of the third inorganic particles is one of the second inorganic particles with a cut plane.

14. The printed wiring board according to claim 1, further comprising:
a plurality of resin insulating layers formed on the second resin insulating layer; and
a plurality of conductor layers formed such that the resin insulating layers and the conductor layers are alternately laminated and that one of the resin insulating layers is covering the second conductor layer formed on the second resin insulating layer.

15. The printed wiring board according to claim 1, wherein each side of the printed wiring board has a length of 50 mm or more.

16. The printed wiring board according to claim 4, further comprising:
a second via conductor formed in a second opening formed in the second resin insulating layer and comprising the second seed layer and the second electrolytic plating layer such that the second via conductor is connecting the first conductor layer and the second conductor layer and that the second via conductor does not have voids in a second connecting portion between the first conductor layer and the second via conductor.

17. The printed wiring board according to claim 2, wherein the first conductor layer has a first conductor circuit having a first width such that the first width is a smallest width in the first conductor layer, the second conductor layer has a second conductor circuit having a second width such that the second width is a smallest width in the second conductor layer and that the first width of the first conductor circuit in the first conductor layer is larger than the second width of the second conductor circuit in the second conductor layer.

18. The printed wiring board according to claim 2, further comprising:
a third resin insulating layer formed on the second resin insulating layer such that the third resin insulating layer is covering the second conductor layer; and
a third conductor layer formed on the third resin insulating layer and comprising a third seed layer and a third electrolytic plating layer formed on the third seed layer,
wherein the third conductor layer is formed such that the third seed layer is an electroless plating layer and that the third conductor layer has voids in at least one of the third seed layer and a boundary portion between the third seed layer and the third electrolytic plating layer.

19. The printed wiring board according to claim 2, wherein the second resin insulating layer includes a resin and inorganic particles such that the inorganic particles include first inorganic particles partially embedded in the resin and second inorganic particles completely embedded in the resin, that each of the first inorganic particles has a first portion protruding from the resin and a second portion embedded in the resin, and that the second resin insulating layer has a surface including a surface of the resin and exposed surfaces of the first portions exposed from the surface of the resin.

20. A printed wiring board, comprising:
a first conductor layer;
a first resin insulating layer laminated on the first conductor layer;
a second conductor layer formed on the first resin insulating layer;
a first via conductor formed in a first opening formed in the first resin insulating layer such that the first via conductor is connecting the first conductor layer and the second conductor layer;
a second resin insulating layer laminated on the first resin insulating layer such that the second resin insulating layer is covering the second conductor layer formed on the first resin insulating layer;
a third conductor layer formed on the second resin insulating layer; and
a second via conductor formed in a second opening formed in the second resin insulating layer such that the second via conductor is connecting the second conductor layer and the third conductor layer,
wherein the first via conductor comprises a first seed layer comprising a sputtering layer and a first electrolytic plating layer formed on the first seed layer such that the first via conductor does not have voids in a connecting portion between the first conductor layer and the first via conductor, and the second via conductor comprises a second seed layer comprising an electroless plating layer and a second electrolytic plating layer formed on the second seed layer such that the second via conductor has voids in a connecting portion between the second via conductor and the second conductor layer.
